(19) United States
(12) Patent Application Publication
(10) Pub. No.: US 2008/0160761 A1
(43) Pub. Date: Jul. 3, 2008

(54) METHOD OF MODIFYING A SURFACE AND A METHOD OF FORMING AN AREA OF A FUNCTIONAL LIQUID ON THE MODIFIED SURFACE

(75) Inventors: Christopher NEWSOME, Cambridge (GB); Shunpu LI, Cambridge (GB); Daping CHU, Cambridge (GB)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 11/942,369

(22) Filed: Nov. 19, 2007

(30) Foreign Application Priority Data
Nov. 22, 2006 (JP) 2006-315193

(51) Int. Cl. H01L 21/44; H01L 21/311

(52) U.S. Cl. 438/679; 438/694; 257/E21.249; 257/E21.476

(57) ABSTRACT

A method of modulating a surface includes: (a) forming a BCB layer on a surface of a target object; and (b) conducting a CF₄ plasma exposure against a top surface of the BCB layer.

The entire disclosure of Japanese Patent Application No. 2006-315193, filed on Nov. 22, 2006, is expressly incorporated by reference herein.

### BACKGROUND

1. Technical Field

Several aspects of this invention relate to methods of modifying a surface and forming an area of a functional liquid on the surface, especially to ones that are preferable for electronic device fabrication utilizing an inkjet printing method.

2. Related Art

Benzo-cyclo-butene (BCB) is a widely used material in electronic devices as a dielectric for isolation between functional layers in the electronic devices. The attractive property of the material is a low dielectric constant (εᵣ<3), which therefore results in a low capacitance between metal tracks or pads in a capacitor structure. The material is commercially available from the Dow Chemical Company under the name “Cyclotene” (trademark) and is provided in solution form, based in mesitylene (or mesythylene). The chemical structure of the material having undergone conversion is shown in FIG. 8. Typical conversion temperatures are between 200° C. and 250° C.

### SUMMARY

In depositing a functional liquid containing, for instance, an electrically conductive material on a free format surface of a substrate using an inkjet printing method, it is required that the surface wetting property of the receiving substrate is carefully prepared and controlled. The wetting behavior of the printed ink, or the deposited functional liquid, defines the lateral dimension of a finally obtained electrically conductive area (such as an electrically conductive track), and thus the maximum resolution of the electrically conductive pattern in an electronic device.

In addition, the surface topography of a substrate may not be flat. Such a feature may be undesirable for attaining thin functional layers (such as a dielectric layer) in subsequent steps especially where such thin layers are non conformal coatings.

An advantage of some aspects of the invention is that an area or a pattern of a predetermined shape may be inkjet printed even if an underlying target object has an uneven surface.

According to one aspect of the invention, a method of modifying a surface includes: (a) forming a BCB layer on a surface of a target object; and (b) conducting a CF₄ plasma exposure against a top surface of the BCB layer.

According to another aspect, there exists a height variation over the surface of the target object, and step (a) includes forming the BCB layer on the surface so that a height variation over the top surface of the BCB layer is reduced compared with that of the surface of the target object.

According to another aspect, step (a) includes forming a precursor layer containing BCB on the surface by spin-coating so that the BCB layer is formed.

According to one aspect of the invention, a method of forming an area of a functional liquid includes: (a) forming a BCB layer on a surface of a target object, (b) conducting a CF₄ plasma exposure against a top surface of the BCB layer; and (c) depositing a functional liquid on the top surface so as to form an area of the functional liquid on the top surface.

According to another aspect, there exists a height variation over the surface of the target object, and step (a) includes forming the BCB layer on the surface so that a height variation over the top surface of the BCB layer is reduced compared with that of the surface of the target object.

According to another aspect, step (a) includes forming a precursor layer containing BCB on the surface by spin-coating so that the BCB layer is formed.

According to another aspect, step (c) includes depositing the functional liquid by an inkjet printing method.

According to another aspect, the area is a track.

According to another aspect, the above-mentioned method further includes (d) heating and/or drying the pattern in the case where the functional liquid contains an electrically conductive material, so that an electrically conductive area containing the electrically conductive material is formed on the top surface.

According to another aspect, the target object is a CMOS chip.

According to another aspect, the top surface is a free format surface.

### BRIEF DESCRIPTION OF THE DRAWINGS

FIGS. 1A and 1B are images obtained by atomic force microscopy, showing the topography of the surface of the CMOS chip of the embodiment, and FIG. 1C shows the height profile along the section line A-A′ in FIG. 1B.

FIGS. 2A and 2B are diagrams illustrating the deposition of the droplets on a native CMOS chip surface in the comparative example.

FIGS. 3A to 3D are diagrams illustrating a procedure of the embodiment.

FIGS. 4A to 4C are diagrams illustrating a procedure of the embodiment.

FIG. 5 is a diagram showing a method of depositing droplets of the embodiment.

FIGS. 6A and 6B are images defined by atomic force microscopy, showing the topography of the top surface of the BCB layer and the track formed on the BCB layer. FIG. 6C shows the height profile along the section line A-A in FIG. 6A. FIG. 6D shows the height profile along the section line B-B in FIG. 6B.

FIG. 7A is a diagram illustrating a cross section of the track formed on the untreated BCB layer in the comparative example, and FIG. 7B is an image of the top surface of the track in FIG. 7A. FIG. 7C is a diagram illustrating a cross section of the track formed on the BCB layer of the embodiment, and FIG. 7D is an image of the top surface of the track in FIG. 7C.

FIG. 8 shows the chemical structure of BCB.

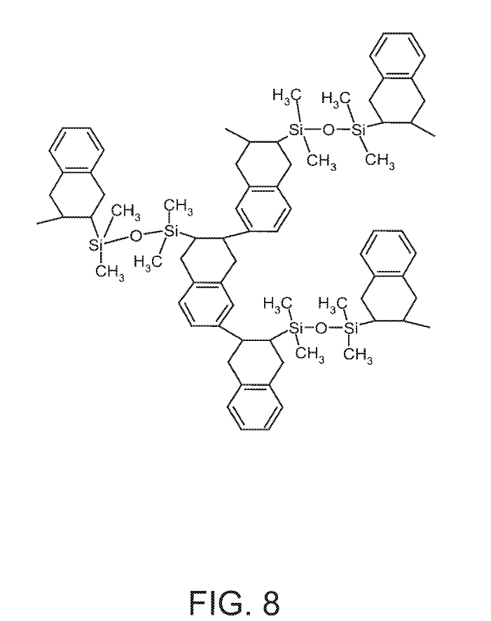

### DESCRIPTION OF EXEMPLARY EMBODIMENTS

In this embodiment, a Benzo-cyclo-butene (BCB) layer is formed on a surface of a target object by spin-coating and subsequent heating. Accordingly, even if a height variation exists over the surface of the target object, it is compensated or reduced by the formation of the BCB layer, and thus a height variation over the top surface of the BCB layer is reduced or canceled compared with that of the surface of the target object. In some cases, the top surface of the BCB layer may become substantially flat.

A carbon tetrafluoride (CF₄) plasma exposure is then conducted against the top surface of the BCB layer, so that the top surface becomes both oleophobic and hydrophobic. Droplets of a functional liquid are then deposited on the top surface of the BCB layer, so that an area of a predetermined shape of the functional liquid is formed on the top surface. In this embodiment, the functional liquid is a liquid-like material that contains a non-polar solvent and silver particles dispersed in the non-polar solvent. Namely, the functional liquid here is a silver colloid.

Since the CF₄ plasma exposure ensures the top surface of the BCB layer being both oleophobic and hydrophobic, a border(s) of the area of the functional liquid is distinct on the top surface even if a “free format” technique is employed in depositing the functional liquid. In the free format technique, there is no bank structure for confining the deposited functional liquid on a surface of a target object, or on an underlying surface for the functional liquid. Throughout the present specification, an underlying surface without such a bank structure may be referred to as a “free format” surface.

In the following example, a CMOS chip is described as an example of a target object, and the topography of the CMOS chip surface is considered. In addition, a technique and conditions to modify the surface wetting characteristic of a BCB layer and an inkjet printing method to deposit the functional liquid on the modified surface are described.

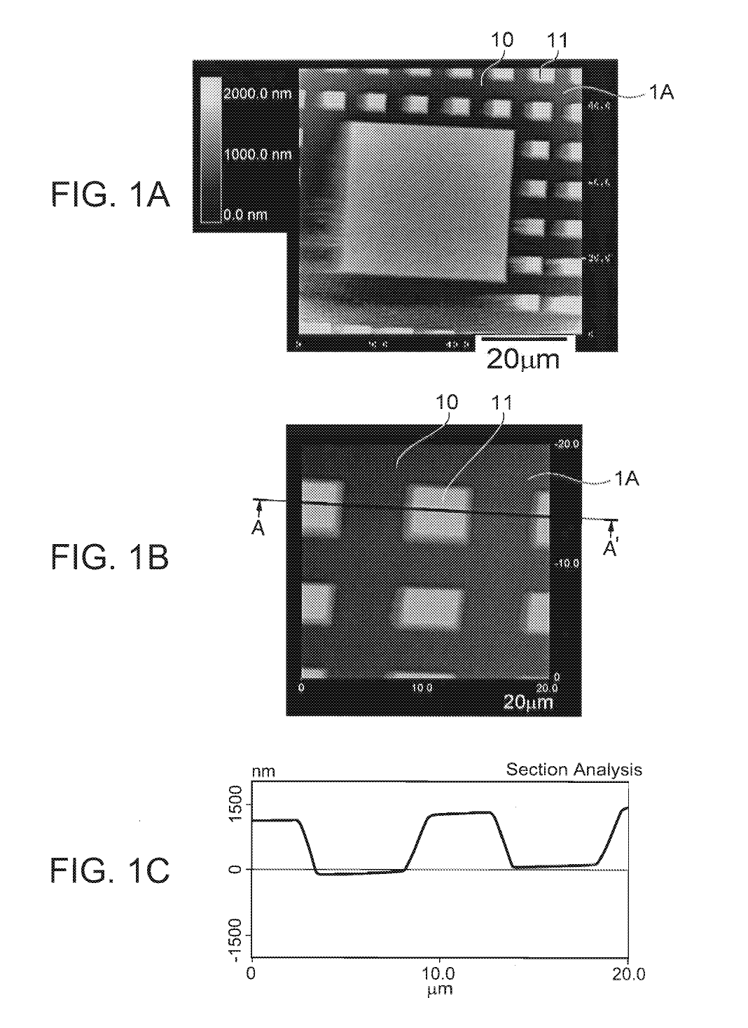

Example: FIGS. 1A-1C show a surface region of a CMOS chip 1A, and they are determined from the measurement by atomic force microscopy. FIG. 1B shows an enlarged part of FIG. 1A. FIG. 1C shows a height profile along the A-A′ line in FIG. 1B.

In FIGS. 1A and 1B, the surface region of the CMOS chip 1A has a dielectric layer 10 and metal islands 11. Each of the metal islands 11 protrudes from the top surface level of the dielectric layer 10. The height of each metal island 11 from the top surface level is about 1 micron. The metal islands 11 are located with gaps between them at the top surface level, and thus a plurality of the metal islands 11 are seen on a background of the dielectric layer 10 throughout the surface region in FIGS. 1A and 1B.

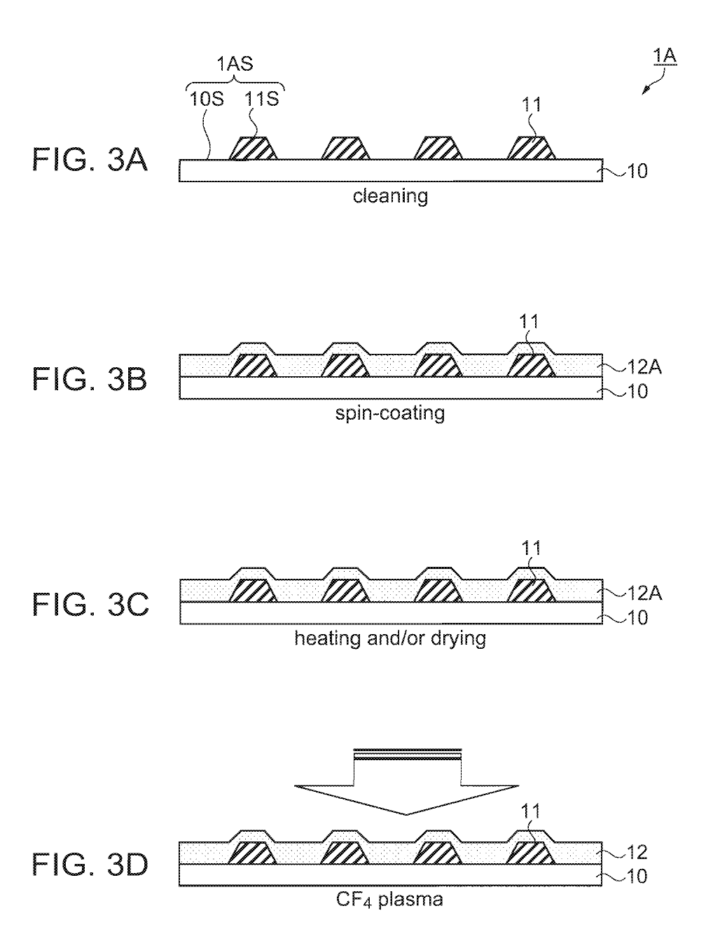

The dielectric layer 10 and the metal islands 11 thus render the surface 1AS (FIG. 3A) of the CMOS chip 1A uneven. In this example, as the height profile in FIG. 1C shows, the surface 1AS may be regarded as consisting of a plurality of indentations and protrusions. The aspect ratio of each protrusion is approximately 1:5 (vertical:horizontal). Such a large height variation over the surface 1AS, or the unevenness, may be undesirable, when thin functional layers are required in subsequent steps.

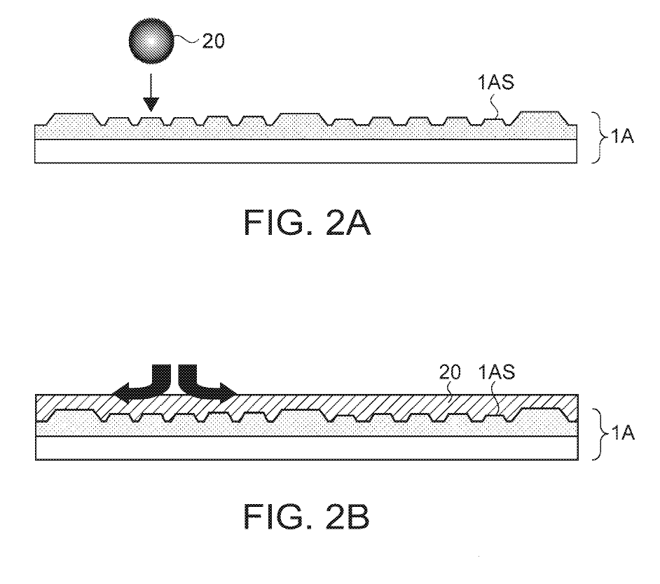

The CMOS chip 1A may be fabricated by conventional silicon integrated circuit techniques. In this example, if the droplets of the functional liquid 20 containing an apolar (i.e., non-polar) solvent are deposited, the surface energy of the CMOS chip 1A is such that the functional liquid 20 rapidly spreads across the surface 1AS causing the surface 1AS to be flooded, as highlighted in FIGS. 2A and 2B.

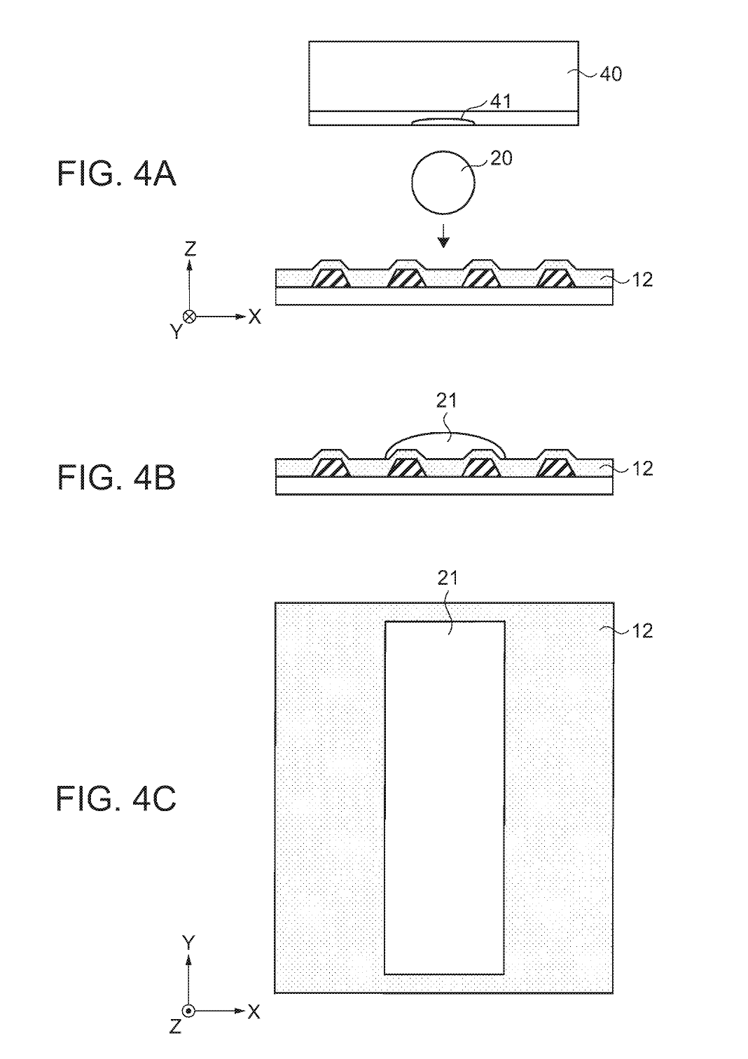

A method of modifying the surface and a method of forming an area of the functional liquid are described in detail here. The BCB layer in this example functions as a planarization layer and a surface treatment layer. FIGS. 3A-3D and FIGS. 4A-4C are referred to in the descriptions below.

The surface 1AS was cleaned first. Specifically, the CMOS chip 1A was cleaned in acetone by an ultrasonic bath for a period of about 10 minutes, then transferred to another ultrasonic bath and cleaned in isopropanol, again for a period of about 10 minutes (FIG. 3A).

A solution containing BCB with mesitylene (or mesythylene) was then spin-coated on the surface 1AS at about 6000 rpm for a period of 30 seconds, so that a precursor layer 12A containing the BCB was formed on the surface 1AS (FIG. 3B). The solution here is “CYCLOTENE” (trademark) 3022-35 available from The Dow Chemical Company.

The precursor layer 12A was then heated so that a BCB layer 12 containing the BCB was formed on the surface 1AS. Specifically in this example, in FIG. 3C the CMOS chip 1 A was set on a hot plate in a dry nitrogen atmosphere, and the temperature was raised at a rate of 5° C. per minute to a target temperature of about 250° C. The temperature was then held at about 250° C. for 1 hour. The CMOS chip 1A was then removed from the hot plate and left to cool to room temperature. The thickness of the BCB layer 12 thus obtained was approximately 1 micron. The contact angle of the functional liquid 20 containing the non polar solvent and the silver particles dispersed in the non polar solvent was measured to be less than 5° on the top surface of the BCB layer 12 at this stage.

According to this example, the BCB layer 12 covers the surface 1AS. In addition, the spin coating step is conducted to form the BCB layer 12. Thus, even if the surface 1AS is uneven, the BCB layer 12 compensates for or cancels the unevenness. As a result, a height variation over the top surface of the BCB layer 12 is reduced compared with that of the underlying surface, or the surface 1AS. In some cases, there may be no substantial height variation over the top surface of the BCB layer 12, that is, the top surface of the BCB layer 12 may become substantially even or flat.

In FIG. 3D, the top surface of the BCB layer 12 was then exposed to the CF₄ plasma. Specifically in this example, the CMOS chip 1A was set in a plasma asher (Technics Plasma GmbbH, model 300), and with a CF₄ flow rate of 150 ml per minute at a power of 150 W for 10 seconds, the CF₄ plasma exposure was conducted against the top surface. Another exposure time in a range from as short as 3 seconds to longer periods of up to 1 minute may also be used, because a difference between exposure times within the range caused no appreciable difference in the wetting characteristic.

The CF₄ plasma exposure ensures that the top surface is both oleophobic and hydrophobic. In this example, the contact angle of the functional liquid 20 containing the non polar solvent and the silver particles dispersed in the non polar solvent was measured to increase to about 37° on the top surface of the BCB layer 12 after the CF₄ plasma exposure. The increase in the contact angle is due to a partial fluorination of the BCB chemical structure.

Next, the CMOS chip 1A was transferred to a stage of an inkjet device (not shown). The inkjet device here has the stage, an inkjet head 40 (FIG. 4A) having nozzles 41 that discharge droplets of the functional liquid 20, a mechanism that moves at least one of the stage and the inkjet head 40 relatively to the other, and a controller. The inkjet device moves at least one of the stage and the inkjet head 40 relatively to the other, and discharges droplets of the functional liquid 20 from the inkjet head 40 in response to a bitmap pattern defined in the discharge data supplied to the controller.

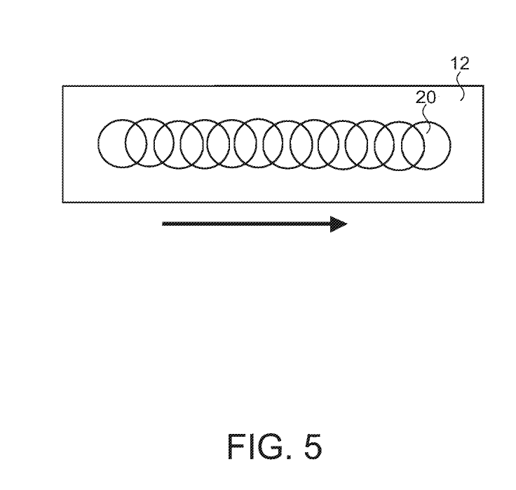

The functional liquid 20 was deposited on the top surface, so that a track 21 of the functional liquid 20 was formed on the top surface of the BCB layer 12 (FIGS. 4A and 4B). Specifically in this example, the droplets of the functional liquid 20 were discharged from the nozzles 41 of the inkjet head 40 and deposited on the top surface of the BCB layer 12. The average volume of the droplets here were approximately 10 pl (picoliter). Also, while discharging the droplets, at least one of the stage and the inkjet head 40 was moved relatively to the other, so that the distance between centers of arbitrary two droplets adjacent to each other on the top surface was 25 microns. In addition, as shown in FIG. 5, of the arbitrary two droplets adjacent to each other on the top surface, one was deposited right before or right after the other, or the droplets were deposited directly after one another. Also, these droplets were deposited in an overlapping manner as shown in FIG. 5, so that the arbitrary two droplets adjacent to each other overlapped one another on the top surface.

As a result, a track 21 of the functional liquid 20 was formed on the BCB layer 12 as shown in FIGS. 4B and 4C. In FIGS. 4A-4C, the track 21 extends in the Y axis direction. In this specification, the direction in which the track 21 extends is also referred to as the “extending direction”.

The above-mentioned overlapping manner is preferable since sufficiently high continuity in the deposited droplets, or the track 211, along the extending direction is ensured. The distance between the adjacent droplet centers may be varied substantially between 20 microns and 35 microns without significantly degrading the continuity of the track 21.

Since the BCB layer 12 was oleophobic due to the CF₄ plasma exposure, the width of the track 21 was confined in a range from 35 microns to 40 microns, the width being measured along a direction perpendicular to the extending direction of the track 21. In addition, the width of the track 211 was highly regular, or constant, on the BCB layer 12. Furthermore, in this example, the borders of the track 21 were distinct. It is important to note that the method of depositing the droplets in this example is by a free format technique, namely, the top surface of the BCB layer 12 is the free format surface. Therefore, the contact angle, which is a measure of the wetting characteristic of the surface, predominantly dictates the lateral track dimension, or the width of the track 21. In addition, the bitmap pattern used to define the distance of the adjacent droplet centers also dictates the uniformity of the tracks 21, and has a particular influence on the continuity along the printing direction, or the extending direction of the track 21.

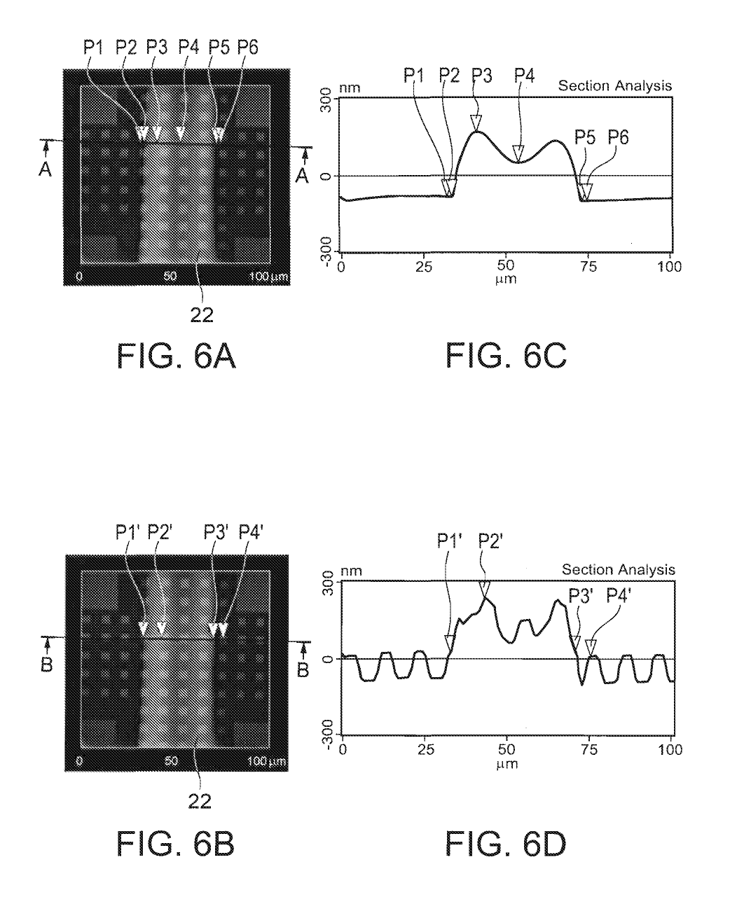

The track 21 was then heated and/or dried, so that an electrically conductive track 22 (FIG. 6A) containing the silver was formed on the top surface of the BCB layer 12.

One of the advantages of the BCB coating, or the BCB layer 12, is the reduction in the height variation induced by the unplanarized surface 1AS of the CMOS chip 1A. It is a standard process in the final step of chip fabrication to form a passivation layer such as silicon dioxide over the entire device. The passivation layer, however, is a conformal coating, or a coating that reflects the shapes of the underlying surface. Therefore, it is difficult for the passivation layer to eliminate the height variation of the unplanarized surface 1AS completely.

Contrary to such a passivation layer of silicon dioxide, the BCB layer 12 is a non conformal coating, and results in the much smoother top surface. The details of the smoother top surface obtained in this example are described below with FIGS. 6A-6D.

FIGS. 6A and 6B are images determined from the measurement by atomic force microscopy of the height of the electrically conductive track 22 formed on the BCB layer 12 covering the CMOS chip 1A. FIG. 6C shows a height profile plotted along the line A-A in FIG. 6A crossing the regions between the metal islands 11. The line A-A also crosses the positions P1 to P6 on the electrically conductive track 22. FIG. 6D shows a height profile plotted along the line B-B in FIG. 6B crossing the regions on the metal islands 11. The line B-B also crosses the positions P1′ to P4′ on the electrically conductive track 22.

From the height profiles in FIGS. 6C and 6D, it is observed that the height variation induced bay the dielectric layer 10 and the metal islands 11 is reduced on the top surface of the BCB layer 12. Initially, on the uncoated CMOS chip 1A (FIGS. 1A-1C), the height variation over the surface 1AS is just over 1 micron (FIG. 1C), by coating the surface 1AS with the BCB layer 12 which itself is about 1 micron in thickness, the height variation is reduced to 100 nm on the top surface of the BCB layer 12. Some of this structure, or the reduced variation, is also evident in the height profiles on the electrically conductive track 22 in FIGS. 6C and 6D. The height profile in FIG. 6A also highlights the height variation of the electrically conductive track 22, which is formed due to the enhanced rate of solvent evaporation at the edge of the track 22 of the functional liquid 20.

Therefore, according to this example, the “free format” technique may be utilized to form an area of the functional liquid 20 with a sufficiently narrow and repeatable lateral dimension that is suitable for electronic devices. The term “area” includes, for instance, at least one of a track-shaped area such as the track 21, a rectangular-shaped area, dot-shaped area, a circle-shaped area and their any combination.

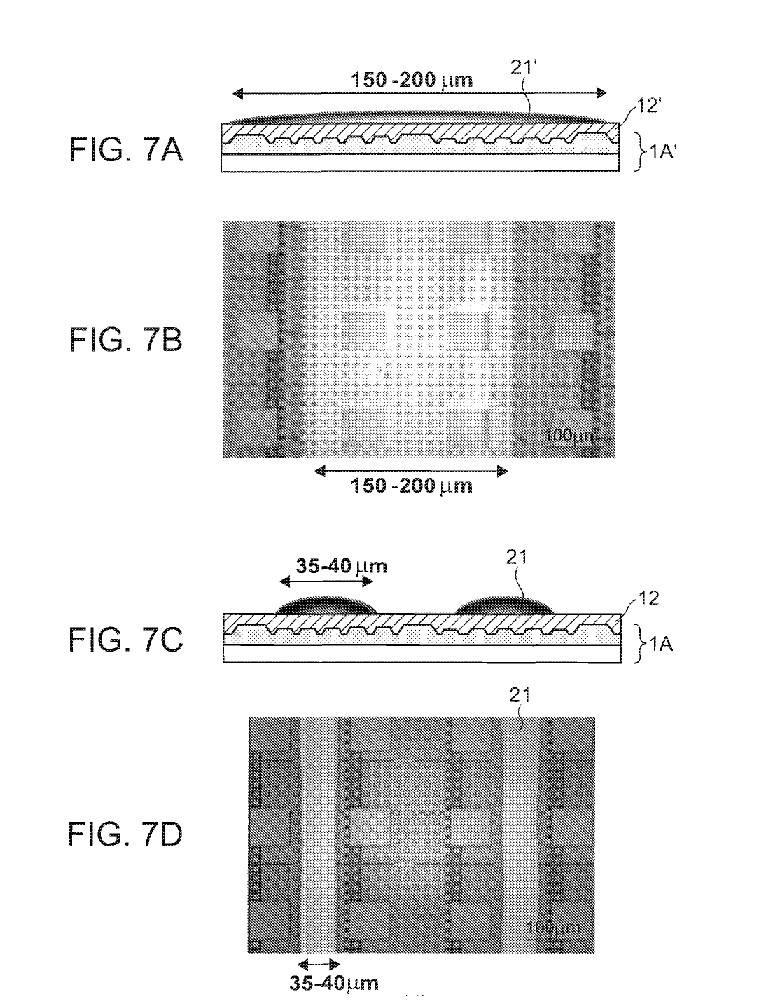

Additionally according to the example, the CF₄ plasma exposure is conducted against the top surface of the BCB layer 12, so that the top surface become oleophobic. Accordingly, the interaction between the polymer surface (the top surface) and the functional liquid 20 decreases, and thus the contact angle of the functional liquid 213 increases. As a result, the width of the track 21, or the lateral track dimension, is well confined and highly regular on the BCB layer 12. Also, the borders of the track 21 are relatively distinct. As mentioned above, the contact angle of the functional liquid 20 is about 37° on the top surface of the BCB layer 12. As shown in FIGS. 7C and 7D, this contact angle causes the width of the track 21 to be in a range from 35 microns to 40 microns when the volume of each droplet from the inkjet head 40 is approximately 10 pl. Also, the variation in the width is less than 5 microns along the extending direction of the track 21.

(Comparative example) A comparative example is described with reference to FIGS. 7A and 7B.

Another target object 1A′ was covered with a BCB layer 12′ basically in the same way as the above-mentioned example. In this comparative example, no CF₄ plasma exposure was conducted against the top surface of the BCB layer 12′. As a result, the contact angle of the functional liquid 20 was measured to be less than 5° on the BCB layer 12′.

The droplets of the functional liquid 20 were then discharged from the inkjet head 40 and deposited on the top surface of the BCB layer 12′, so that a track 21′ of the functional liquid 20 was formed. The volume of the droplets and the bitmap pattern for the inkjet device to discharge the droplets were the same as those in the above-mentioned examples As a result, as shown in FIGS. 7A and 7B, the width of the track 21′ thus obtained was measured to vary substantially in a range from 150 microns to 200 microns on the BCB layer 12′.

Modifications: According to the above-mentioned example, the track 21 is formed on the BCB layer 12. Instead of the track 21, however, an area of any shape may be formed on the BCB layer 12. Regard less of its shape, the area with a distinct border is attained on the BCB layer 12.

According to the above-mentioned example, the top surface of the BCB layer 12 is not only oleophobic but also hydrophobic due to the CF₄ plasma exposure. Therefore, even if another functional liquid containing a polar solvent instead of the non polar one is used to form the track 21, the same advantages as the case of the non polar one are obtained.

According to the example described above, the functional liquid 20 is the silver colloid. Thus, the functional liquid 20 contains the silver particles as an electrically conductive material. However, the functional liquid 20 may contain other metal particles or an electrically conductive polymer such as PEDOT as an electrically conductive material. Furthermore, the functional liquid 20 may contain a semiconductor material or a dielectric material.

The foregoing descriptions has been given by way of example only and it will be appreciated by a person skill in the art that more modifications can also be made without departing from the scope of the invention.

What is claimed is:

1. A method of modifying a surface, the method comprising:
(a) forming a benzo-cyclo-butene layer over a portion of a target object; and
(b) conducting a CF₄ plasma exposure against a portion of the benzo-cyclo-butene layer.

2. The method according to claim 1, the portion of the target object having a first height variation, the portion of the benzo-cyclo-butene layer having a second height variation that is more flat than the first height variation.

3. The method according to claim 1, the forming the benzo-cyclo-butene layer including forming a precursor layer including benzo-cyclo-butene over the portion of the target object by spin-coating.

4. A method of forming an area of a functional liquid, the method comprising:
(a) forming a benzo-cyclo-butene layer over a portion of a target object,
(b) conducting a CF₄ plasma exposure against a portion of the benzo-cyclo-butene layer; and
(c) depositing a functional liquid over the portion of the benzo-cyclo-butene layer so as to form an area of the functional liquid over the portion of the benzo-cyclo-butene layer.

5. The method according to claim 4, the portion of the target object having a first height variation, the portion of the benzo-cyclo-butene layer having a second height variation that is more flat than the first height variation.

6. The method according to claim 4, the forming the benzo-cyclo-butene layer including forming a precursor layer including benzo-cyclo-butene over the portion of the target object by spin-coating.

7. The method according to claim 4, the forming the benzo-cyclo-butene layer including forming a precursor layer including benzo-cyclo-butene over the portion of the target object by an inkjet printing method.

8. The method according to claim 4, the area being a track.

9. The method according to claim 4, further including:
(d) evaporating the area of the functional liquid that includes a conductive material, so that a conductive area including the conductive material is formed over the portion of the benzo-cyclo-butene layer.

10. The method according to claim 4, the target object being a CMOS chip.

11. The method a according to claim 4, the portion of the benzo-cyclo-butene layer having a free format surface.
